(19) United States
(12) Patent Application Publication
(10) Pub. No.: US 2019/0385874 A1
(43) Pub. Date: Dec. 19, 2019

(54) METHODS AND APPARATUS FOR RECONFIGURABLE FLOW CONTROL IN PROCESS CHAMBERS

(71) Applicant: APPLIED MATERIALS, INC., Santa Clara, CA (US)

(72) Inventors: PREETHAM P. RAO, SINGAPORE (SG); MADHUKAR C GULEDGUDD, BENGALURU (IN); ANANTHKRISHNA JUPUDI, SINGAPORE (SG); RIBHU GAUTAM, BENGALURU (IN); TUCK FOONG KOH, SINGAPORE (SG)

(21) Appl. No.: 16/010,899

(22) Filed: Jun. 18, 2018

(51) Int. Cl. H01L 21/67; G05D 7/00

(52) U.S. Cl. CPC H01L 21/67253; G05D 7/00

(57) ABSTRACT

Methods and apparatus for controlling gas flow in a process chamber use reconfigurable gas flow plates. The gas flow plates are configured based on at least one processing parameter in the process chamber and then inserted into the process chamber such that a gas flow into an internal volume of the process chamber is controlled by the gas flow plate. The configuration of the gas flow plate may be based on a type of processing, dimensions of the internal volume of the processing chamber, a number of substrates to be processed in the processing chamber, and other parameters. The gas flow plate may include changeable parameters such as a number of through holes, through hole diameters, orientation of through holes, or a position of through holes relative to spacing between substrates.

### FIELD

Embodiments of the present principles generally relate to semiconductor process chambers.

### BACKGROUND

Many semiconductor processes require the flow of gases through a process chamber during processing. The gas flow may be part of the process such as the flow of oxygen to enhance oxidizing steps or may be part of setting up a process such as evacuating a chamber or conditioning a chamber. Flowing gases can be used for deposition of materials such as in a lateral flow deposition chamber or for removing unwanted gases given off during degassing or to aid in removing moisture from substrates. Although the flow of gases may be a common denominator in the different processes, the parameters of the flowing gases vary greatly, even within a single type of process. The inventors have observed that the gas flow parameters are typically determined when the process chamber is designed and cannot be easily varied once the chamber is in operation.

Thus, the inventors have provided improved methods and apparatus for optimizing gas flow in a semiconductor process chamber.

### SUMMARY

Methods and apparatus for controlling gas flow in semiconductor process chambers.

In some embodiments, an apparatus for controlling gas flow in a process chamber comprises at least one gas flow plate insertable into a side wall of an internal volume of a process chamber, the least one gas flow plate having a plurality of through holes such that gas flowing through the plurality of through holes is directed into the internal volume of the process chamber.

In some embodiments, the apparatus further comprises wherein the at least one gas flow plate is opaque to microwaves, wherein at least one of the plurality of through holes has a diameter different from at least one other hole of the plurality of through holes, wherein at least one of the plurality of through holes has an orientation through the at least one gas flow plate different from at least one other hole of the plurality of through holes, wherein at least one of the plurality of through holes has a diameter of approximately four millimeters, wherein the at least one gas flow plate has a flat or curved gas outlet surface, wherein at least one of the plurality of through holes has a diameter of between greater than zero and approximately five millimeters, wherein the at least one gas flow plate is configured to flow gas at a rate of approximately 1,000 standard cubic centimeter per minute (sccm) to approximately 25,000 sccm, a gas flow control assembly removable from the process chamber, wherein the gas flow control assembly forms a portion of a side wall of the internal volume and provides at least one mounting location for the at least one gas flow plate, and/or wherein the gas flow control assembly has at least one gas flow cavity fluidly coupled and adjacent to the at least one mounting locating for the at least one gas flow plate.

In some embodiments, an apparatus for processing semiconductors comprises a process chamber with an internal volume for processing and at least one gas flow plate removable from a wall of the internal volume of the process chamber, the gas flow plate having a plurality of through holes such that gas flowing through the plurality of through holes is directed into the internal volume of the process chamber from at least one gas flow cavity.

In some embodiments, the apparatus further comprises wherein the process chamber is a degas chamber, a microwave chamber, or a lateral flow deposition chamber; wherein the process chamber is configured to process a plurality of substrates in a stacked formation; wherein the plurality of through holes of the at least one gas flow plate form at least one row of through holes that align with at least one space between substrates when present in the process chamber; and/or wherein the at least one gas flow plate including a first gas flow plate with a first plurality of through holes configured to flow a first gas and a second gas flow plate with a second plurality of through holes configured to flow a second gas.

In some embodiments, a method of controlling gas flow in a process chamber comprises selecting a first set of at least one gas flow plate such that a gas flow pattern for a process in an internal volume of the process chamber is achieved and removably inserting the first set of at least one gas flow plate into the process chamber such that a gas flow into an internal volume of the process chamber is controlled at least partially by the first set of at least one gas flow plate.

In some embodiments, the method further comprises selecting the first set of at least one gas flow plate based at least partially on a number of through holes, at least one through hole diameter, orientation of at least one through hole, or a position of at least one through hole relative to spacing between substrates to aid in achieving the gas flow pattern; selecting the first set of at least one gas flow plate based at least partially on at least one processing parameter including a type of processing, dimensions of the internal volume of the processing chamber, a number of substrates to be processed in the processing chamber, spacing between stacked substrates to be processed in the processing chamber, gas flow pressure and gas flow rate for a gas to be used in the processing chamber, or materials of substrates to be processed in the processing chamber; and/or selecting a second set of at least one gas flow plate when at least one parameter changes and removably inserting the second set of at least one gas flow plate into the process chamber such that a gas flow into an internal volume of the process chamber is controlled at least partially by the second set of at least one gas flow plate.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional top view of a process chamber in which an apparatus for controlling gas flow may be employed or a method of controlling gas flow may be performed in accordance with some embodiments of the present principles.

FIG. 2 depicts an isometric view of a gas flow control assembly in accordance with some embodiments of the present principles.

FIG. 3 depicts an isometric view of a gas flow plate in accordance with some embodiments of the present principles.

FIG. 4 depicts a cross-sectional top view of gas flow through a gas flow plate in accordance with some embodiments of the present principles.

FIG. 5 depicts a cross-sectional top view of through hole patterning in a gas flow plate in accordance with some embodiments of the present principles.

FIG. 6 depicts a front view of a gas flow plate in accordance with some embodiments of the present principles.

FIG. 7 is a method of controlling gas flow in a process chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Gas flow is important for effective moisture removal during the processing of packaging wafers. The wafers are typically heated in batches, and the moisture is removed. If the moisture is not purged effectively, the wafers may re-absorb moisture resulting in a low yield for the moisture removal process. The flow rate, direction, and pressure of a gas may change for different batch sizes, wafer types, and heating patterns. The methods and apparatus of the present principles allow for an easily reconfigurable gas flow control system for different processing conditions and different process chambers. The high flexibility of the methods and apparatus advantageously provide optimal flow conditions in the same chamber for any given processing condition including, but not limited to, different pressure regimes and heating non-uniformities, preventing loss of quality of degas or yield. The inventors have found that multiple optima can exist for multiple process conditions, and the methods and apparatus beneficially allow for such conditions.

The methods and apparatus allow for the removal and re-configurability of the gas flow plate for processing substrates in a process chamber. Different gas flow plates with different patterns of flow through holes can be replaced easily in a process chamber for different process conditions. The methods and apparatus may be used with, but is not limited to, curing, degas, and lateral flow deposition chambers, and the like. In some embodiments, an optimal condition may be obtained for thermal and degas uniformities when conditions for process, wafer types, or wafer positions change. The methods and apparatus also advantageously allow testing of different conditions and scenarios based on, but not limited to, wafer types, positions, and operating pressures. The high flexibility of gas flow control is especially beneficial for microwave degas chambers where heating uniformity is very sensitive to different process conditions, and gas flow has to be adjusted accordingly.

The methods and apparatus provide one or more removable gas flow plates with a plurality of through holes to control gas flow into an internal volume of a process chamber. In some embodiments, the through holes may differ from gas flow plate to gas flow plate in diameter, number, diameter spread within the holes, and the angles of the holes (orientation). During a process, the operating pressure, ramp, and soak durations may be decided based on the required temperatures and wafer types. For example, an epoxy wafer may have a different heat up rate and soak temperature compared to that of a silicon wafer with a polyimide layer or a thinner wafer. The wafer positions may also need to be changed due to the heat distribution (e.g., in the case of microwave based processes) which also depends on wafer positions. In some embodiments, based on, but not limited to, the process selected, the through holes in the gas flow plates may be configured either numerically or experimentally by multiple iterations or with the use of multiple computational models. The end choice of the gas flow plates may be such as to obtain minimum residual moisture in the wafers, with a maximum uniformity of purge on each wafer.

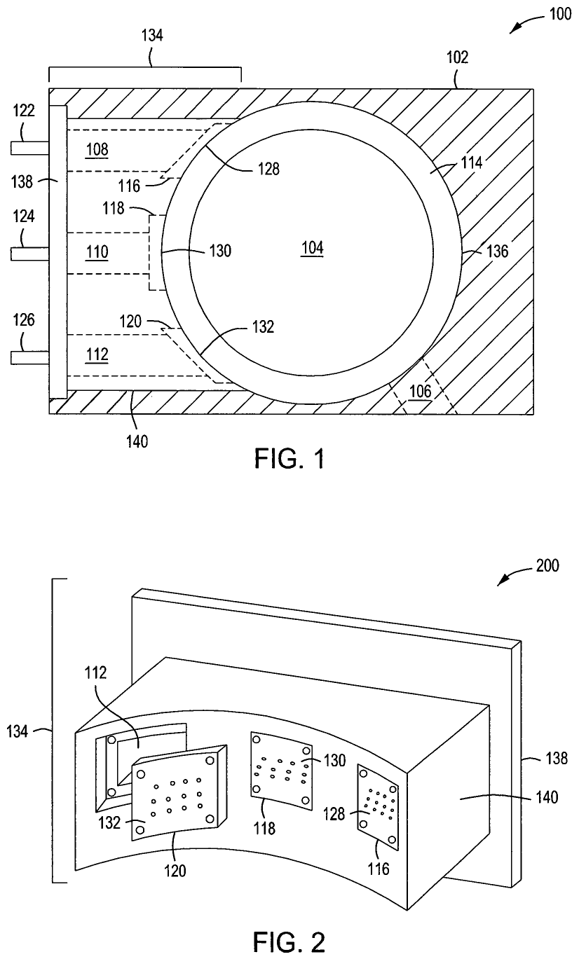

FIG. 1 depicts a cross-sectional top view 100 of a process chamber 102 in which an apparatus for controlling gas flow may be employed or a method of controlling gas flow may be performed in accordance with some embodiments. The process chamber 102 includes an internal volume 114 that may hold one or more substrates 104 for processing. The internal volume 114 may be of any shape or size. The process chamber 102 includes one or more gas inlets 122-126 and one or more gas outlets 106. In some embodiments, the gas inlets 122-126 may provide the same gas, different gases, or different mixtures of gases. In some embodiments, the process chamber 102 may include a gas flow control assembly 134. The gas flow control assembly 134 may be removable from the process chamber 102 for servicing and include an outer flange 138 that mates with the process chamber and a flow chamber portion 140 that may include one or more gas flow cavities 108-112. In the illustrated example, the gas inlets 122-126 are attached to the gas flow control assembly 134. The gas flow control assembly 134 may have one or more gas flow cavities 108-112 that join with one or more gas flow plates 116-120. The gas flow plates 116-120 may have gas flow plate outlet surfaces 128-132 that form portions of a wall 136 of the internal volume 114 of the process chamber 102. In some embodiments, the gas flow plate outlet surfaces 128-132 may conform to a shape of the wall 136 of the internal volume 114 of the process chamber 102. The gas flow plates 116-120 are opaque to microwaves and may be used in process chambers that employ microwaves during processing without affecting performance of the microwave processing.

FIG. 2 depicts an isometric view 200 of the gas flow control assembly 134 of FIG. 1 in accordance with some embodiments. The gas flow plates 116-120 are removable and may be secured using screws or at least partially held in place using a tab or protrusion on an edge that interacts with the flow chamber portion 140. The gas flow control assembly 134 may be removed from the process chamber 102 to allow removal and insertion of the gas flow plates 116-120. In some embodiments without a gas flow control assembly 134 that is removable, the gas flow plates 116-120 may be removed and inserted directly from the wall 136 of the internal volume 114 of the process chamber 102. Most types of process chambers have a removable lid that allows servicing inside the internal volume of the process chamber.

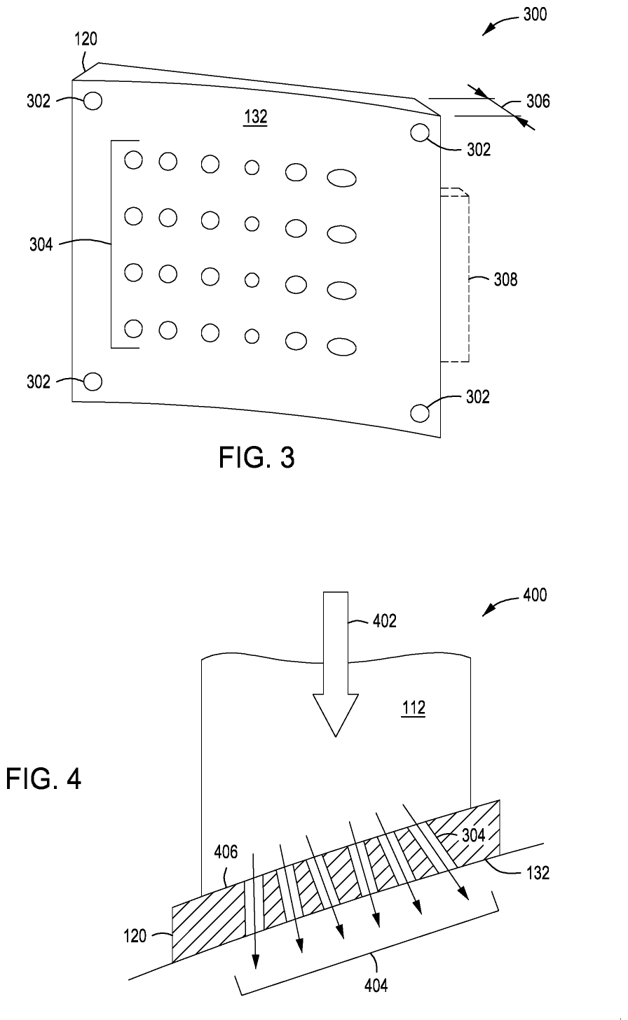

FIG. 3 depicts an isometric view 300 of a gas flow plate 120 in accordance with some embodiments. The gas flow plate 120 may include one or more securing holes 302 to secure the gas flow plate 120 to the wall 136 of the internal volume 114 of the process chamber 102. In some embodiments, the gas flow plate 120 may include one or more tabs or protrusions 308 that interact with the wall 136 of the internal volume 114 to at least partially secure the gas flow plate 120. The one or more protrusions 308 may be located on a side, top, or bottom edge of the gas flow plate 120. In some embodiments, the one or more protrusions 308 may emerge from a back side of the gas flow plate 120 and provide a hook-type protrusion to interact with an inner lip of the gas flow cavity 112. The gas flow plate outlet surface 132 has a plurality of through holes 304 that control gas flow from the gas flow cavity 112 into the internal volume 114 of the process chamber 102. The size, number, orientation, positioning of the plurality of through holes 304 may be varied to achieve a particular flow pattern within the internal volume 114 of the process chamber 102. In some embodiments, a thickness 306 of the gas flow plate may also be varied to achieve a particular flow pattern within the internal volume 114 of the process chamber 102.

FIG. 4 depicts a cross-sectional top view 400 of a gas flow 402 through the gas flow plate 120 in accordance with some embodiments. The gas flow 402 is introduced into the gas flow cavity 112 (indicated by an arrow) to a gas flow plate inlet surface 406 where the gas flow 402 is controlled by the plurality of through holes 304. The controlled gas flow emerges from the gas flow plate outlet surface 132 as gas outflow 404. In some embodiments, gas flow parameters such as, for example, direction, volume, pressure, and flow rate may be affected by the plurality of through holes 304 in the gas flow plate 120.

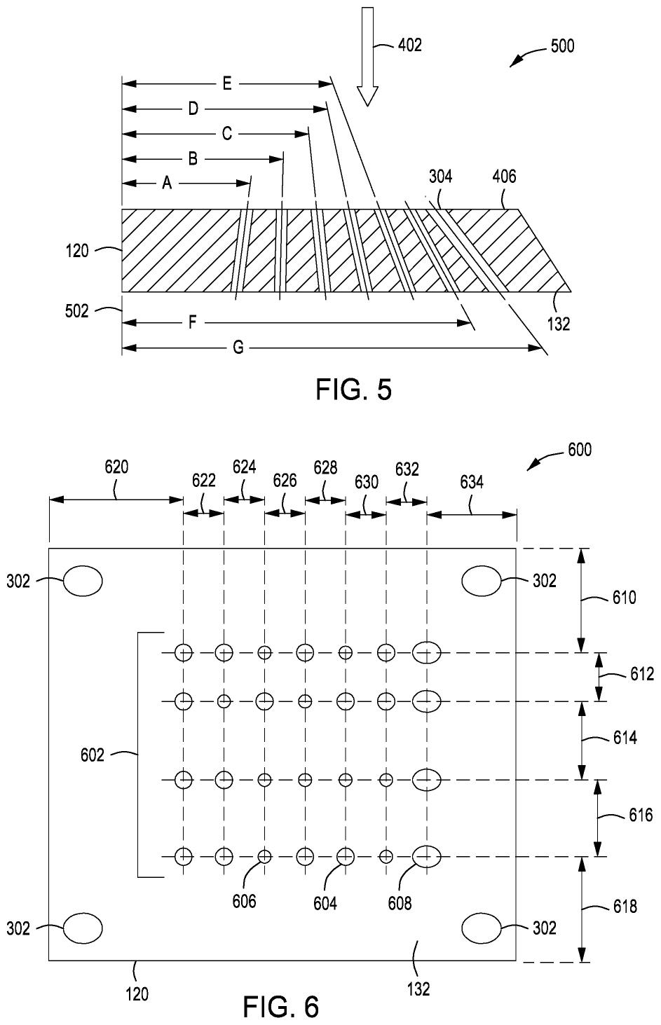

FIG. 5 depicts a cross-sectional top view 500 of through hole patterning in a gas flow plate in accordance with some embodiments. The orientation or angle of the through holes may different between one or more of the through holes. Different angles A-G based on a reference line 502 may be used for the plurality of through holes 304. In some embodiments, the angles A-G of the plurality of through holes 304 spread the gas flow 402 outward in a horizontal plane. In some embodiments, other angles based on other reference lines may spread the gas flow 402 outward in a vertical plane. In some embodiments, other angles based on other reference lines may spread the gas flow 402 outward in both horizontal and vertical planes.

FIG. 6 depicts a front view 600 of the gas flow plate 120 in accordance with some embodiments. A plurality of through holes 602 in the gas flow plate 120 may comprise rows and columns. The plurality of through holes 602 may include a set of first diameter holes 606 with a first set of orientations, a set of second diameter holes 604 with a second set of orientations, and a set of third diameter holes 608 with a third set of orientations. In some embodiments, the plurality of through holes 602 may include fewer sets of diameters and orientations or more sets of diameters and orientations. The sets of orientations may include a horizontal angle, a vertical angle, or a combination of a vertical and a horizontal angle (vector). The spacing 610, 618, 620, 634 of a row of the plurality of through holes 602 from an edge of the gas flow plate 120 may be varied based on, but not limited to, placement of the gas flow plate 120 within the internal volume 114 of the process chamber 102, angle of the gas flow plate 120 relative to the wall 136 of the internal volume 114 of the process chamber 102, or angle of the gas flow plate 120 relative to a direction of an incoming flow of gas to be controllably dispersed within the internal volume 114 by the gas flow plate 120.

In some embodiments, the spacing 612-616 between rows of the plurality of through holes 602 may be varied to align with the spacing between substrates in the internal volume 114 of the process chamber 102 or based on a determined flow pattern in the internal volume 114 of the process chamber 102 and the like. In some embodiments, the column spacing 622-632 of the plurality of through holes 602 may be varied based on the orientation of a particular through hole, size of a particular through hole, or a particular determined dispersion of the gas flow within the internal volume 114 and the like. In some embodiments, a row of the plurality of through holes 602 may be linear or non-linear (e.g., offset or randomly dispersed above or below a linear line). In some embodiments, a row of the plurality of through holes 602 may be of the first diameter with more than one orientation. In some embodiments, a row of the plurality of through holes 602 may be of the first diameter with the same orientation. In some embodiments, a row of the plurality of through holes may have a plurality of diameters and one or more orientations. Similarly, in some embodiments, a column of the plurality of through holes 602 may be linear or non-linear and may have one or more diameters with one or more orientations. In some embodiments, a row or column may not have evenly spaced through holes or a complete set of through holes for the column or row.

The through hole sizes or diameters may be varied based on a particular flow pattern for the internal volume 114 of the process chamber 102. The inventors have found that the diameters of the through holes may range from greater than zero to approximately five millimeters. The inventors have also found that an approximately four millimeter through hole size advantageously provides an enhanced flow pattern. The inventors have also found that advantageous flow rates may vary from approximately 1,000 standard cubic centimeter per minute (sccm) to approximately 25,000 sccm.

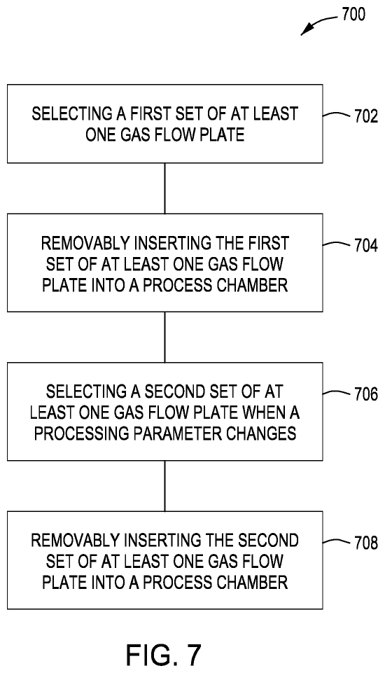

FIG. 7 is a method 700 of controlling gas flow in a process chamber in accordance with some embodiments. In block 702, a first set of at least one gas flow plate is selected. The first set may include one gas flow plate or may include multiple gas flow plates. The selection is based on a gas flow pattern in an internal volume of a process chamber that is to be achieved for a given process or process chamber. In some embodiments, the first set of at least one gas flow plate may effectively control the gas flow within the internal volume or may act in conjunction with other gas flow sources to control the gas flow within the internal volume. In some embodiments, the processing parameters that may affect selection of the first set of at least one gas flow plate may include, but are not limited to, a type of processing being done in the process chamber, dimensions of the internal volume of the processing chamber, a number of substrates to be processed in the processing chamber, spacing between stacked substrates to be processed in the processing chamber, gas flow pressure and gas flow rate for a gas to be used in the processing chamber, and/or materials of the substrates to be processed in the processing chamber and the like. In some embodiments, the selecting of the first set of at least one gas flow plate may be based at least partially on a number of through holes, at least one through hole diameter, orientation of at least one through hole, and/or a position of at least one through hole relative to spacing between substrates to aid in achieving the gas flow pattern and the like.

In block 704, the selected first set of at least one gas flow plate is removably inserted into the process chamber such that at least one gas flow into an internal volume of the process chamber is controlled at least partially by the first set of at least one gas flow plate. As discussed above, the gas flow plate may be inserted as part of a wall of the internal volume of the process chamber. In some embodiments, the gas flow plate may be removably inserted by using screws and the like. In some embodiments, the gas flow plate may be secured, at least partially, by an insertion tab or protrusion and the like that interacts with the wall of the internal volume. The gas flow plate is opaque to microwaves and will not interfere with processes such as drying or curing processes that employ microwaves.

In block 706, a second set of at least one gas flow plate is selected when at least one process parameter changes. In some embodiments, the second set of at least one gas flow plate may include at least a portion of the first set of at least one gas flow plate. The changed parameter may require additional flow rates, less flow rates, and/or different orientations of through holes in a gas flow plate and the like. In block 708, the second set of at least one gas flow plate is removably inserted into the process chamber. In some embodiments, the second set of at least one gas flow plate may include one or more gas flow plates of the first set of at least one gas flow plate.

In some embodiments, the gas flow plates may be interchanged based on uniformity and/or temperature control parameters that are adjusted to enhance a process. The first or second set of gas flow plates may be selected and removably inserted into the process chamber to effect better performance of a process rather than based on a process parameter change. The inventors have found that the configurability and the removability of the gas flow plates greatly enhances the flexibility afforded to an operator of a process chamber to maximize both performance and productivity of a process chamber.

While the foregoing is directed to embodiments of the present principles, other and further embodiments of the principles may be devised without departing from the basic scope thereof.

1. An apparatus for controlling gas flow in a process chamber, comprising:
at least one gas flow plate insertable into a side wall of an internal volume of a process chamber, the at least one gas flow plate having a plurality of through holes such that gas flowing through the plurality of through holes is directed into the internal volume of the process chamber.

2. The apparatus of claim 1, wherein the at least one gas flow plate is opaque to microwaves.

3. The apparatus of claim 1, wherein at least one of the plurality of through holes has a diameter different from at least one other hole of the plurality of through holes.

4. The apparatus of claim 1, wherein at least one of the plurality of through holes has an orientation through the at least one gas flow plate different from at least one other hole of the plurality of through holes.

5. The apparatus of claim 1, wherein at least one of the plurality of through holes has a diameter of approximately four millimeters.

6. The apparatus of claim 1, wherein the at least one gas flow plate has a flat or curved gas outlet surface.

7. The apparatus of claim 1, wherein at least one of the plurality of through holes has a diameter of between greater than zero and approximately five millimeters.

8. The apparatus of claim 1, wherein the at least one gas flow plate is configured to flow gas at a rate of approximately 1,000 standard cubic centimeter per minute (sccm) to approximately 25,000 sccm.

9. The apparatus of claim 1, wherein the plurality of through holes form at least one row.

10. The apparatus of claim 1, further comprising:
a gas flow control assembly removable from the process chamber, wherein the gas flow control assembly forms a portion of a side wall of the internal volume and provides at least one mounting location for the at least one gas flow plate.

11. The apparatus of claim 10, wherein the gas flow control assembly has at least one gas flow cavity fluidly coupled and adjacent to the at least one mounting location for the at least one gas flow plate.

12. An apparatus for processing semiconductors, comprising:
a process chamber with an internal volume for processing; and
at least one gas flow plate removable from a wall of the internal volume of the process chamber, the gas flow plate having a plurality of through holes such that gas flowing through the plurality of through holes is directed into the internal volume of the process chamber from at least one gas flow cavity.

13. The apparatus of claim 12, wherein the process chamber is a degas chamber, a microwave chamber, or a lateral flow deposition chamber.

14. The apparatus of claim 12, wherein the process chamber is configured to process a plurality of substrates in a stacked formation.

15. The apparatus of claim 14, wherein the plurality of through holes of the at least one gas flow plate form at least one row of through holes that align with at least one space between substrates when present in the process chamber.

16. The apparatus of claim 12, wherein the at least one gas flow plate including a first gas flow plate with a first plurality of through holes configured to flow a first gas and a second gas flow plate with a second plurality of through holes configured to flow a second gas.

17. A method of controlling gas flow in a process chamber, comprising:
selecting a first set of at least one gas flow plate such that a gas flow pattern for a process in an internal volume of the process chamber is achieved; and
removably inserting the first set of at least one gas flow plate into the process chamber such that a gas flow into an internal volume of the process chamber is controlled at least partially by the first set of at least one gas flow plate.

18. The method of claim 17, further comprising:
selecting the first set of at least one gas flow plate based at least partially on a number of through holes, at least one through hole diameter, orientation of at least one through hole, or a position of at least one through hole relative to spacing between substrates to aid in achieving the gas flow pattern.

19. The method of claim 17, further comprising:
selecting the first set of at least one gas flow plate based at least partially on at least one processing parameter including a type of processing, dimensions of the internal volume of the processing chamber, a number of substrates to be processed in the processing chamber, spacing between stacked substrates to be processed in the processing chamber, gas flow pressure and gas flow rate for a gas to be used in the processing chamber, or materials of substrates to be processed in the processing chamber.

20. The method of claim 19, further comprising:
selecting a second set of at least one gas flow plate when at least one parameter changes; and
removably inserting the second set of at least one gas flow plate into the process chamber such that a gas flow into an internal volume of the process chamber is controlled at least partially by the second set of at least one gas flow plate.
